(19) United States
(12) Patent Application Publication
(10) Pub. No.: US 2009/0283834 A1
(43) Pub. Date: Nov. 19, 2009

(54) SEMICONDUCTOR DEVICE AND MANUFACTURING METHOD THEREOF

(76) Inventor: Hideki Inokuma, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/407,644

(22) Filed: Mar. 19, 2009

(30) Foreign Application Priority Data
May 14, 2008 (JP) 2008-127024

(51) Int. Cl. H01L 27/092; H01L 21/8234

(52) U.S. Cl. 257/368; 438/301; 257/E27.062; 257/E21.616

(57) ABSTRACT

A MOS semiconductor device including MOSFETs each of which has a gate portion formed on a semiconductor substrate and source/drain regions includes sidewall insulating films formed on the side portions of the gate portions in the gate length direction, alloy layers formed on the source/drain regions, taper adjusting insulating films that are formed on the side portions of the sidewall insulating films and in which a taper angle made between a cross section thereof in the gate length direction and the substrate surface is set smaller than a taper angle made between the sidewall insulating film and the substrate surface, a stress-causing insulating film that applies strains to channels and is formed to cover the gate portions, sidewall insulating films and taper adjusting insulating films, and an interlayer insulating film formed on the stress-causing insulating film.

### CROSS-REFERENCE TO RELATED APPLICATIONS

This application is based upon and claims the benefit of priority from prior Japanese Patent Application No. 2008-127024, filed May 14, 2008, the entire contents of which are incorporated herein by reference.

### BACKGROUND OF THE INVENTION

1. Field of the Invention

This invention relates to a MOS semiconductor device and a manufacturing method thereof for applying strains to channel regions of MOSFETs to enhance the mobility.

2. Description of the Related Art

Conventionally, in a semiconductor device having MOSFETs or the like, a plurality of gate electrodes are arranged on a semiconductor substrate and source/drain regions are formed on the substrate surface portion on both sides of each channel region below the gate electrode. Sidewall insulating films (sidewall spacers) are formed on the side portions of the respective gate electrodes, a contact etching stop film (CESL film) is formed to cover the gate electrodes and sidewall insulating films and an interlayer insulating film is formed thereon. Interconnections are connected to the source/drain regions of the MOSFETs by forming contact holes in the interlayer insulating film and filling interconnection metals in the contact holes.

In order to increase the drive current of the MOSFET, a method for depositing an insulating film (stress-causing insulating film) having a high or strong stress as the CESL film and applying a stress to the channel region to lower the resistance thereof is often utilized (for example, see Jpn. Pat. Appln. KOKAI Publication No. 2007-67118).

However, in the semiconductor device of this type, the following problems are provided. That is, it is desirable to deposit a thick CESL film having strong stress in order to increase the drive current of the MOSFET, and at the same time, it is desirable to narrow the distance between adjacent gate electrodes in order to lower the cost. If a thick CESL film is deposited in a semiconductor device in which the distance between the gate electrodes is made narrow, there occurs a problem that voids occur in the interlayer insulating film and the CESL film between the gate electrodes. If two contacts are brought into contact with the void, a problem that a metal to be filled in the contact will enter the void and short-circuit the contacts occurs.

### BRIEF SUMMARY OF THE INVENTION

According to one aspect of this invention, there is provided a MOS semiconductor device which includes MOSFETs formed on a semiconductor substrate, each MOSFET including a gate portion formed on the semiconductor substrate and source/drain regions formed on a surface portion of the substrate to sandwich a channel under the gate portion, sidewall insulating films formed on side portions of the gate portions in a gate length direction, alloy layers formed on the source/drain regions, a position of each alloy layer being defined by the sidewall insulating films, taper adjusting insulating films formed in contact with the alloy layers on side portions of the sidewall insulating films, a taper angle made between the taper adjusting insulating film in a cross section in the gate length direction and the substrate surface being set smaller than a taper angle made between the sidewall insulating film and the substrate surface, a stress-causing insulating film that gives strains to channels of the MOSFETs, the stress-causing insulating film being formed to cover the gate portions, sidewall insulating films and taper adjusting insulating films, and an interlayer insulating film formed on the stress-causing insulating film.

According to another aspect of this invention, there is provided a MOS semiconductor device which includes p-MOSFETs formed on a semiconductor substrate, each p-MOSFET including a gate portion formed on the semiconductor substrate and source/drain regions formed on a surface portion of the substrate to sandwich a channel under the gate portion, n-MOSFETs formed on a semiconductor substrate, each n-MOSFET including a gate portion formed on the semiconductor substrate and source/drain regions formed on the surface portion of the substrate to sandwich a channel under the gate portion, sidewall insulating films formed on side portions of the gate portions of the respective MOSFETs in a gate length direction, alloy layers formed on the source/drain regions of the respective MOSFETs, a position of each alloy layer being defined by the sidewall insulating films, taper adjusting insulating films formed in contact with the alloy layers on side portions of the sidewall insulating films of the respective MOSFETs, a taper angle made between a cross section of the taper adjusting insulating film in the gate length direction and the substrate surface being set smaller than a taper angle made between the sidewall insulating film and the substrate surface, a first stress-causing insulating film that gives compressive strains to channels of the p-MOSFETs, the stress-causing insulating film being formed to cover the gate portions of the p-MOSFETs, sidewall insulating films and taper adjusting insulating films, a second stress-causing insulating film that gives tensile strains to channels of the n-MOSFETs, the stress-causing insulating film being formed to cover the gate portions of the n-MOSFETs, sidewall insulating films and taper adjusting insulating films, and an interlayer insulating film formed on the first and second stress-causing insulating films.

According to a further aspect of this invention, there is provided a MOS semiconductor device manufacturing method which includes forming MOSFETs by forming gate portions on a semiconductor substrate and forming source/drain regions formed on a surface portion of the substrate to respectively sandwich channels under the gate portions, forming sidewall insulating films on side portions of the gate portions in a gate length direction, forming alloy layers whose positions are defined by the sidewall insulating films on the source/drain regions, forming a taper adjusting insulating film to cover the gate portions, sidewall insulating films and alloy layers, etching back the taper adjusting insulating film to leave portions of the taper adjusting insulating film that lie on lower portions of side portions of the sidewall insulating films and set a taper angle made between the taper adjusting insulating film in a cross section in the gate length direction and the substrate surface smaller than a taper angle made between the sidewall insulating film and the substrate surface, forming a stress-causing insulating film that gives strains to channels of the MOSFETs to cover the gate portions, sidewall insulating films and taper adjusting insulating film, and forming an interlayer insulating film on the stress-causing insulating film.

### BRIEF DESCRIPTION OF THE SEVERAL VIEWS OF THE DRAWING

FIG. 1 is a cross-sectional view showing the schematic structure of a semiconductor device according to a first embodiment of this invention.

FIGS. 2A to 2G are cross-sectional views showing manufacturing steps of the semiconductor device according to the first embodiment.

FIG. 3 is a cross-sectional view showing the schematic structure of a semiconductor device according to a second embodiment of this invention.

FIGS. 4A to 4D are cross-sectional views showing manufacturing steps of the semiconductor device according to the second embodiment.

FIGS. 5A to 5D are cross-sectional views showing manufacturing steps of a general semiconductor device.

FIG. 6 is a plan view for illustrating a problem of the semiconductor device manufactured by the steps of FIGS. 5A to 5D.

### DETAILED DESCRIPTION OF THE INVENTION

Before explaining embodiments of this invention, a general manufacturing method of a semiconductor device is explained.

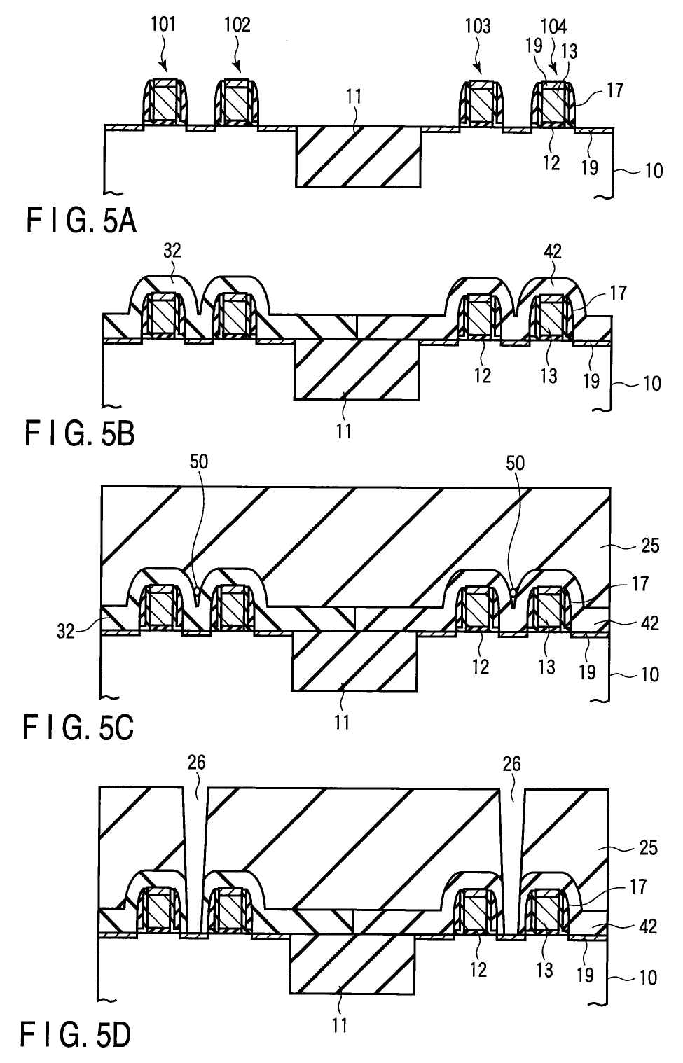

First, as shown in FIG. 5A, an element isolation region 11 is formed on a silicon substrate 10, gate electrodes 13 are formed above the silicon substrate 10 with gate insulating films 12 disposed therebetween, then sidewall insulating films 17 are formed on the side portions of the gate electrodes 13 and silicide layers 19 are formed on the gate electrodes 13 and source/drain regions. In this case, it is supposed that a plurality of gate portions 101, 102, 103, 104 are formed on the substrate 10, the gate portions 101, 102 are arranged on the left side of the element isolation region 11 and the gate portions 103, 104 are arranged on the right side of the element isolation region 11.

Next, as shown in FIG. 5B, CESL films 32, 42 having strong stress are deposited to cover the upper surfaces of the source/drain regions and gate electrodes 13 so as to apply stresses to respective channels. At this time, it is known effective that a film that exerts a tensile stress is used for nMOSFETs and a film that exerts compressive stress is used for pMOSFETs, and therefore, the CESL films 32, 42 can be separately formed for the nMOSFETs and pMOSFETs.

Then, as shown in FIG. 5C, an interlayer insulating film 25 is deposited on the CESL films 32, 42 and the upper surface thereof is made flat.

Subsequently, as shown in FIG. 5D, contact holes 26 used to connect metal interconnections to the silicide layers 19 on the source/drain regions or the silicide layers 19 on the gate electrodes 13 are formed. In the succeeding process, although not shown in the drawing, W and a barrier metal such as TiN are filled in the contact holes 26 and then metal interconnections and a passivation film are formed.

In the above semiconductor device, it is desirable to deposit a thick CESL film having strong stress in order to increase the drive current of the transistor, and at the same time, it is desirable to narrow the distance between the adjacent gate electrodes 13 in order to lower the cost.

According to the study by the inventors of this application and others, in a case where the distance between the adjacent gate electrodes 13 is approximately 100 nm and the thickness of the sidewall insulating film 17 in the lateral direction is 20 nm, it is necessary to set the thickness of the CESL film to at least approximately 40 nm in order to exert a sufficiently strong stress to the transistor. That is, it is desirable to set the thickness of the CESL film larger than ½ or more times the distance between the adjacent gate electrodes 13, more precisely, the distance between the gate portions including the sidewall insulating films 17.

If the distance between the first and second gate portions 101 and 102 and the distance between the third and fourth gate portions 103 and 104 are short and the CESL film is deposited thick, there occurs a problem that voids 50 will occur in the CESL film 32 lying between the first and second gate portions 101 and 102, in the CESL film 42 lying between the third and fourth gate portions 103 and 104 or in the interlayer insulating film 25. If two contacts are brought into contact with the void 50, there occurs a problem that metal to be filled into the contacts enters the void and short-circuits the contacts.

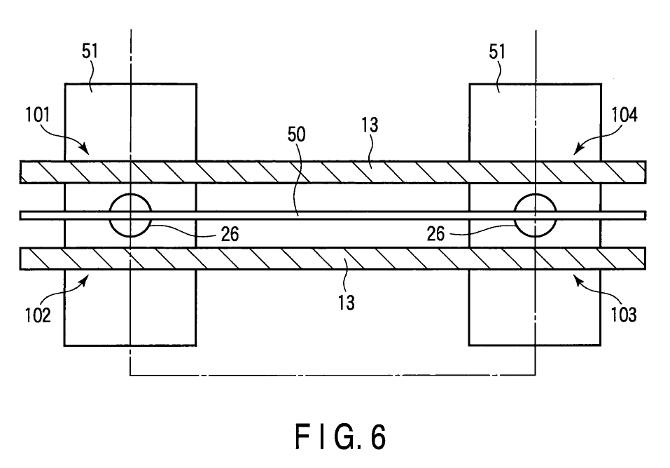

FIG. 6 is a plan view in the step of FIG. 5D, for illustrating the above problem. The cross section taken along the one-dot-dash line in FIG. 6 corresponds to the cross section of FIG. 5D. If a void 50 is continuously formed between two contacts 26 respectively formed in adjacent active regions 51 and when metal is filled into the contacts 26, metal enters the void 50 and short-circuits the contacts.

Therefore, in the embodiment of this invention, occurrence of voids is suppressed to prevent contacts from being short-circuited. Next, the embodiments of this invention are explained with reference to the accompanying drawings.

### First Embodiment

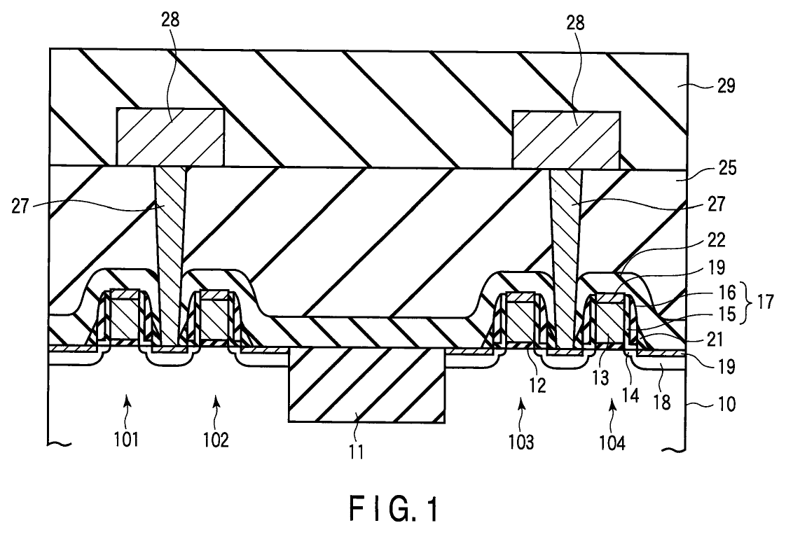

FIG. 1 is a cross-sectional view showing the schematic structure of a semiconductor device according to a first embodiment of this invention. The cross section corresponds to the cross section taken along the one-dot-dash line in the plan view of FIG. 6.

A symbol 10 in FIG. 1 denotes a silicon substrate (semiconductor substrate). An element isolation region 11 is formed on part of the surface portion of the substrate 10. A plurality of gate portions 101, 102, 103, 104 are formed on the substrate 10. In this case, the first and second gate portions 101, 102 are separated with a distance of approximately 100 nm and arranged on the left side of the element isolation region 11 and the third and fourth gate portions 103, 104 are separated with a distance of approximately 100 nm and arranged on the right side of the element isolation region 11. Each of the gate portions 101 to 104 is configured by forming a gate electrode 13 formed of poly-Si with a thickness of approximately 100 nm while a gate insulating film 12 having a thickness of approximately 1 nm is disposed therebetween. Although not shown in the drawing, a gate electrode 13 is formed above the element isolation region 11 with a gate insulating film 12 disposed therebetween.

Extension regions 14 of the source/drain regions are formed on those portions of the substrate surface that sandwich a channel region below each gate electrode 13. On the side surfaces of each gate electrode 13, sidewall insulating films 17 formed of insulating films 15, 16 are formed. Further, source/drain regions 18 are formed outside the extension regions 14 that sandwich the gate electrode 13. Silicide layers (alloy layers) 19 for lowering the resistances are formed on the source/drain regions 18 and gate electrodes 13.

The structure explained so far is the same as that of a general semiconductor device, but in this embodiment, taper adjusting insulating films 21 are formed on the lower portions of the side surfaces of the sidewall insulating films 17. The taper adjusting insulating films 21 are formed in contact with the silicide layers 19 on the side portions of the sidewall insulating films 17. A taper angle made between the side surface (the side surface on the opposite side of the sidewall insulating film 16) of the taper adjusting insulating film 21 in the cross section in the gate length direction (the vertical direction of the active region 51 of FIG. 6) and the substrate surface is set smaller than a taper angle made between the side surface (the side surface on the opposite side of the gate electrode 13) of the sidewall insulating film 17 and the substrate surface. That is, a taper angle made between the bottom surface and the side surface of the taper adjusting insulating film 21 is set smaller than a taper angle made between the bottom surface and the side surface of the sidewall insulating film 17.

As a material of the taper adjusting insulating film 21, a general insulating film such as a silicon oxide film or silicon nitride film can be used, but it is desirable to use a material that is the same as that of a CESL film in order to apply a large strain to the channel, as will be described later.

A CESL film (stress-causing insulating film) 22 that functions as a stopper at the contact etching time and applies a strain to the channel region is formed to cover the gate portions 101 to 104, sidewall insulating films 17 and taper adjusting insulating films 21. An interlayer insulating film 25 is formed on the CESL film 22. Via plugs 27 that are brought into contact with the silicide layers 19 on the source/drain regions 18 are formed in the interlayer insulating film 25. On the interlayer insulating film 25, metal interconnections 28 that are brought into contact with the via plugs 27 are formed. Then, a passivation film 29 is formed on the metal interconnections 28 and interlayer insulating film 25.

Next, a semiconductor device manufacturing method of this embodiment is explained.

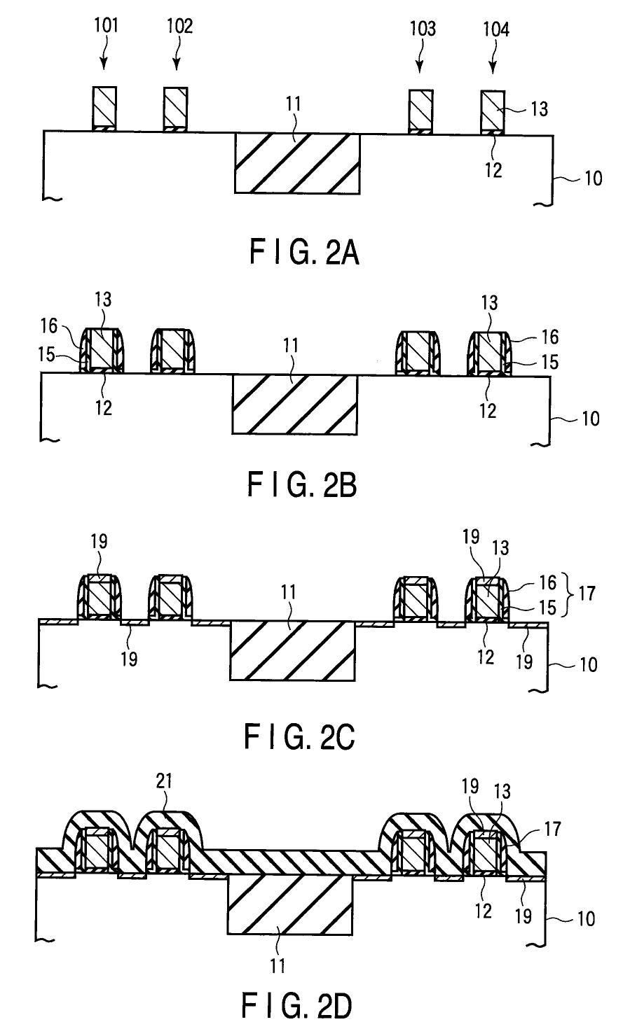

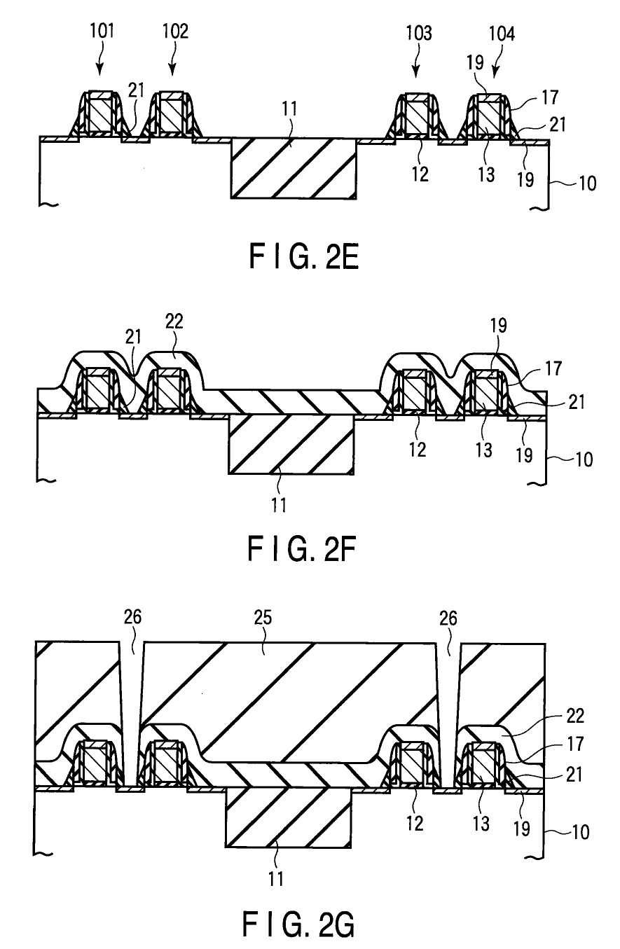

First, as shown in FIG. 2A, gate electrodes 13 formed of polysilicon with a thickness of approximately 100 nm are formed above a silicon substrate 10 on which an element isolation region 11 formed by filling an insulating film into a groove with a depth of approximately 300 nm while gate insulating films 12 with a thickness of approximately 1 nm are disposed therebetween. Thus, first to fourth gate portions 101 to 104 are formed.

Then, as shown in FIG. 2B, source/drain extension regions 14 (not shown) are formed by doping an n-type impurity such as As, P or the like into an element region including the first and second gate portions 101, 102 among the first to fourth gate portions that will be used as nMOS portions. Further, source/drain extension regions 14 (not shown) are formed by doping a p-type impurity such as B, BF₂, In or the like into an element region including the third and fourth gate portions 103, 104 that will be used as pMOS portions.

Subsequently, a silicon oxide film 15 with a thickness of 10 nm and a silicon nitride film 16 with a thickness of 20 nm are deposited and then the silicon nitride film 16 is processed into a sidewall shape by anisotropic etching with the silicon oxide film 15 used as a stopper. After this, sidewall insulating films 17 formed of the silicon oxide films 15 and silicon nitride films 16 are formed by removing exposed portions of the silicon oxide films 15.

Then, as shown in FIG. 2C, source/drain regions 18 (not shown) are formed by doping an n-type impurity such as As, P or the like into the element region including the first and second gate portions 101, 102. Further, source/drain regions 18 (not shown) are formed by doping a p-type impurity such as B, BF₂, In or the like into the element region including the third and fourth gate portions 103, 104. Subsequently, Ti, Co, Ni or the like used for lowering the interconnection resistance is deposited. Next, a heat treatment is performed to selectively form alloys with the surfaces of the gate electrodes and the surfaces of the source/drain regions so as to form silicide layers 19.

Then, as shown in FIG. 2D, for example, a taper adjusting insulating film 21 formed of a silicon nitride film is deposited to such a film thickness that the narrow spaces between the gate electrodes will not be completely filled. Specifically, if the distance between the gates is set to 100 nm and the film thickness of the sidewall insulating film 17 in the lateral direction is set to 20 nm, the taper adjusting insulating film 21 is deposited to a thickness of 40 nm by a plasma CVD method.

Next, as shown in FIG. 2E, the taper adjusting insulating film 21 is etched back and processed into a sidewall shape by anisotropic etching and left behind only on the lower portions of the side surfaces of the sidewall insulating films 17. By the etch-back process, a taper angle made between the side surface of the taper adjusting insulating film 21 that lies on the opposite side of the sidewall insulating film 16 and the substrate surface becomes smaller than a taper angle made between the side surface of the sidewall insulating films 17 that lies on the opposite side of the gate electrode 13 and the substrate surface.

Then, as shown in FIG. 2F, a CESL film 22 having strong stress is deposited to cover the upper surfaces of the source/drain potions and gate portions in order to exert stresses to the channel regions (particularly, apply tensile stresses to the channels of the nMOS portions). Specifically, for example, a CESL film 22 formed of a silicon nitride film is deposited to a thickness of 50 nm by a plasma CVD method. At this time, since the taper adjusting insulating films 21 are formed, voids will not occur in narrow portions between the gate electrodes.

Next, as shown in FIG. 2G, an interlayer insulating film 25 with a thickness of approximately 400 nm is deposited on the CESL film 22 and the surface thereof is made flat. At this time, since the taper angles are reduced by the presence of the taper adjusting insulating films 21 that are processed into the sidewall shape and added to the outside portions of the respective sidewall insulating films 17, the filling ability of the CESL film 22 and interlayer insulating film 25 can be enhanced. Therefore, even when a thick CESL film 22 is deposited, occurrence of voids in the CESL film 22 and interlayer insulating film 25 can be prevented. Then, contact holes 26 for connecting metal interconnections to the source/drain regions or gate electrodes are formed.

In the succeeding process, W and a barrier metal such as TiN are filled in the contact holes 26 and metal interconnections 28 and a passivation film 29 are formed to form the semiconductor device with the structure shown in FIG. 1.

Thus, according to this embodiment, the filling ability of the CESL film 22 and the interlayer insulating film 25 formed thereon can be enhanced by forming the taper adjusting insulating films 21 on the outside portions of the respective sidewall insulating films 17 to reduce the taper angles. As a result, occurrence of voids in the CESL film 22 and interlayer insulating film 25 can be prevented. Therefore, a thick CESL film 22 can be formed without causing voids, and a large drive current and high reliability can be attained.

Further, stresses can be applied to the channel regions due to the presence of the taper adjusting insulating films 21 by forming the taper adjusting insulating films 21 with the same material as that of the CESL film 22. That is, forming the taper adjusting insulating films 21 avoids the problem of a reduction in the stress applied to the channel regions.

### Second Embodiment

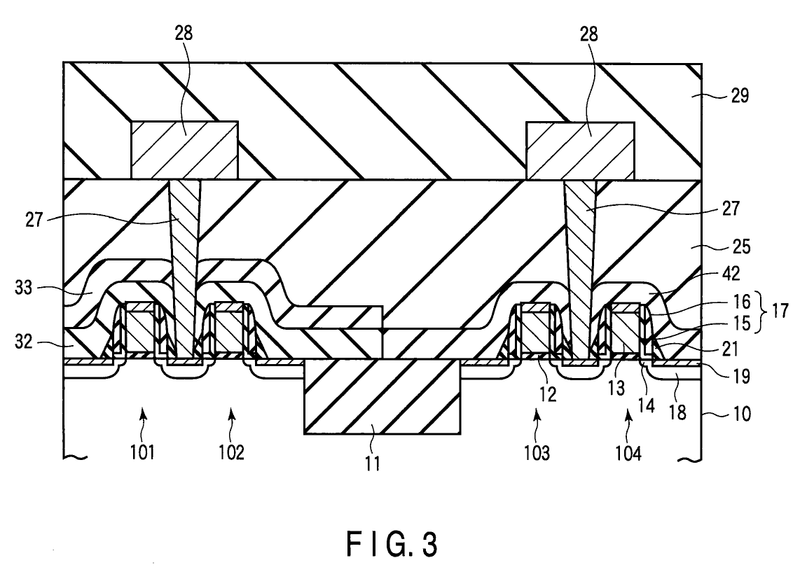

FIG. 3 is a cross-sectional view showing the schematic structure of a semiconductor device according to a second embodiment of this invention. Portions that are the same as those of FIG. 1 are denoted by the same reference symbols and the detailed explanation thereof is omitted.

This embodiment is different from the first embodiment explained before in that stress-causing insulating films for nMOSFETs and pMOSFETs are formed of different materials and stresses are applied to the nMOSFETs and pMOSFETs in different directions.

That is, a CESL film 32 that functions as a stopper at the contact etching time and applies a tensile stress to the channels is formed to cover gate portions 101, 102, sidewall insulating films 17 and taper adjusting insulating films 21 on the nMOSFET side. Further, an insulating film 33 formed of a material different from that of the CESL film 32 is formed on the CESL film 32. On the other hand, a CESL film 42 that functions as a stopper at the contact etching time and applies compressive stresses to the channels is formed to cover gate portions 103, 104, sidewall insulating films 17 and taper adjusting insulating films 21 on the pMOSFET side.

In this case, a silicon nitride film can be used as the CESL film 32 and a silicon nitride film can be used as the CESL film 42. Further, the CESL films 32, 42 may be formed of the same material, the film density of the CESL film 32 may be set low and the film density of the CESL film 42 may be set high.

Like the case of the first embodiment, an interlayer insulating film 25 is formed on the CESL films 32, 42 and via plugs 27 that are brought into contact with silicide layers 19 on source/drain regions 18 are formed in the interlayer insulating film 27. Metal interconnections 28 that make contact with the via plugs 27 are formed on the interlayer insulating film 25. Further, a passivation film 29 is formed on the metal interconnections 28 and interlayer insulating film 25.

Next, a semiconductor device manufacturing method according to this embodiment is explained.

First, a process that is the same as the process up to the step shown in FIG. 2E in the first embodiment is performed. That is, like the first embodiment, silicide layers 19 are formed on source/drain regions 18 and gate electrodes 13 and then taper adjusting insulating films 21 are formed on the outside portions of sidewall insulating films 17.

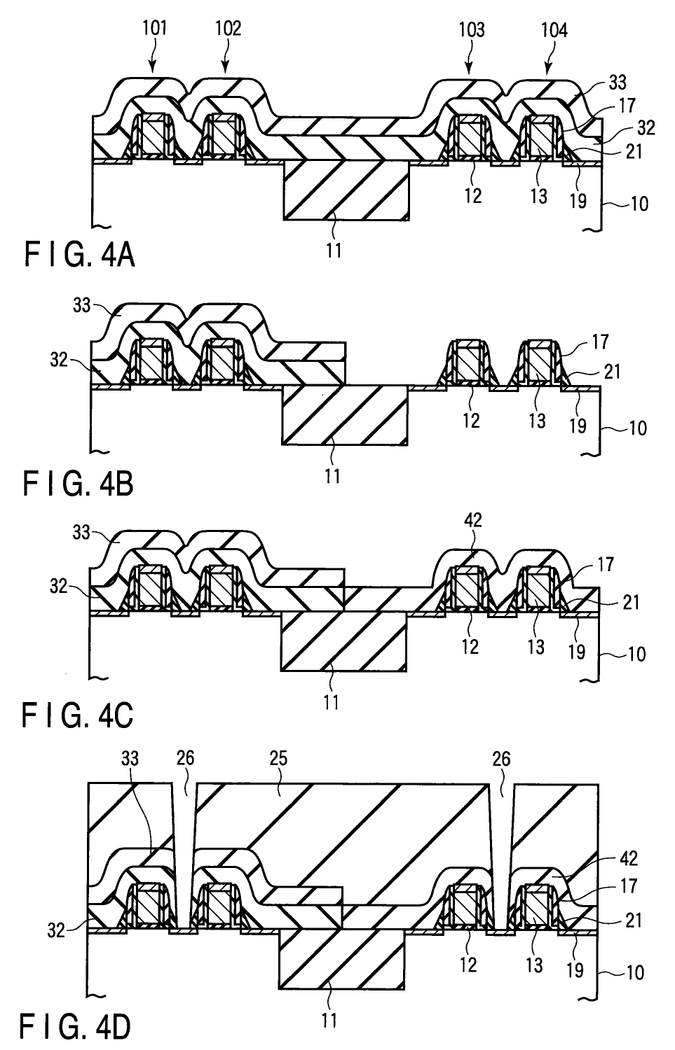

Next, as shown in FIG. 4A, a CESL film 32 formed of a silicon nitride film that exerts tensile stresses to the channel regions and an insulating film 33 having a certain selective etching ratio with respect to the CESL film are deposited for nMOS portions.

Then, as shown in FIG. 4B, a resist film (not shown) is formed to cover the nMOS portions, and the CESL film 32 and insulating film 33 formed in the PMOS region are removed by dry etching. After this, the resist film is removed.

Subsequently, as shown in FIG. 4C, a CESL film 42 formed of a silicon nitride film that exerts compressive stresses to the channel regions is deposited for pMOS portions. Then, a resist film (not shown) is formed to cover the pMOS region and the CESL film 42 formed in the nMOS region is removed by dry etching. After this, the resist film is removed. Thus, the CESL films 32, 42 for the nMOS and pMOS portions are separately formed.

Like the first embodiment, in the succeeding process, an interlayer insulating film 25 and contact holes 26 are formed as shown in FIG. 4D. Further, metal interconnections 28 and a passivation film 29 are formed to complete the semiconductor device with the structure shown in FIG. 3.

In this example, the CESL films are formed in an order of nMOS→pMOS, but the order can be reversed. The taper adjusting insulating film 21 formed into the sidewall shape before the CESL film that is first formed is deposited may be formed of any insulating film, but it is considered that it may be formed of a film having the same stress as that of the CESL film 32 first formed for the nMOSFETs in order to attain a large drive current. In this case, since the taper adjusting insulating film 21 formed on the outside portion of the sidewall insulating film 17 has a stress that is opposite that of a subsequently formed CESL film 42 for the pMOSFETs, it can be removed or the volume thereof may be reduced when the CESL films 32, 42 are separately formed in a case where a problem related to the filling process does not occur.

Thus, according to this embodiment, the same effect as that of the first embodiment can be of course attained and the following effect can be attained. That is, since the CESL films 32, 42 that apply different stresses to the nMOS and pMOS portions are independently formed, optimum strains can be applied to the channels of the respective MOSFETs.

(Modification)

This invention is not limited to the above embodiments. In the above embodiment, MOSFETs are formed on the Si substrate, but this invention can be applied to a semiconductor device in which MOSFETs are formed on an SOI substrate. Further, the substrate is not necessarily limited to Si, and an SiGe substrate can be used.

In addition, the material of the taper adjusting insulating film is not limited to a silicon nitride film, and can be adequately modified according to the specification. Specifically, the material may be an insulating film that is formed to set a taper angle made between the cross section thereof in the gate length direction and the substrate surface smaller than a taper angle made between the sidewall insulating film and the substrate surface and maintain the taper angles by etching back. Also, the stress-causing insulating film can be appropriately modified.

Further, the silicon oxide film is used for the gate insulating film of each MOSFET in the above embodiment, but an insulating film other than a silicon oxide film can be used as the gate insulating film. That is, the MOSFET referred to in this invention contains a MISFET.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A MOS semiconductor device comprising:
MOSFETs formed on a semiconductor substrate, each MOSFET having a gate portion formed on the semiconductor substrate and source/drain regions formed on a surface portion of the substrate to sandwich a channel under the gate portion,
sidewall insulating films formed on side portions of the gate portions in a gate length direction,
alloy layers formed on the source/drain regions, a position of each alloy layer being defined by the sidewall insulating films,
taper adjusting insulating films formed in contact with the alloy layers on side portions of the sidewall insulating films, a taper angle made between the taper adjusting insulating film in a cross section in the gate length direction and the substrate surface being set smaller than a taper angle made between the sidewall insulating film and the substrate surface,
a stress-causing insulating film that applies strains to channels of the MOSFETs, the stress-causing insulating film being formed to cover the gate portions, sidewall insulating films and taper adjusting insulating films, and
an interlayer insulating film formed on the stress-causing insulating film.

2. The semiconductor device according to claim 1, wherein the MOSFETs are arranged side by side in the gate length direction.

3. The semiconductor device according to claim 2, wherein adjacent MOSFETs commonly use one of the source/drain regions.

4. The semiconductor device according to claim 1, wherein the taper adjusting insulating film is formed of the same material as that of the stress-causing insulating film.

5. The semiconductor device according to claim 1, wherein the taper adjusting insulating film is formed of either a silicon oxide film or a silicon nitride film.

6. The semiconductor device according to claim 1, wherein the semiconductor substrate is formed of Si and the stress-causing insulating film is formed of a silicon nitride film.

7. The semiconductor device according to claim 1, wherein the sidewall insulating film is formed of a double-layered structure having a silicon oxide film and silicon nitride film.

8. The semiconductor device according to claim 1, wherein the MOSFETs include both of pMOSFETs and nMOSFETs formed on the substrate and the stress-causing insulating film includes stress-causing insulating films formed for the respective MOSFETs.

9. The semiconductor device according to claim 8, wherein the materials and film qualities of the stress-causing insulating films for the pMOSFETs and nMOSFETs are different from each other to apply tensile stresses to the channels of the nMOSFETs and apply compressive stresses to the channels of the pMOSFETs.

10. A MOS semiconductor device comprising:
p-MOSFETs formed on a semiconductor substrate, each p-MOSFET having a gate portion formed on the semiconductor substrate and source/drain regions formed on a surface portion of the substrate to sandwich a channel under the gate portion,
n-MOSFETs formed on a semiconductor substrate, each n-MOSFET having a gate portion formed on the semiconductor substrate and source/drain regions formed on the surface portion of the substrate to sandwich a channel under the gate portion,
sidewall insulating films formed on side portions of the gate portions of the respective MOSFETs in a gate length direction,
alloy layers formed on the source/drain regions of the respective MOSFETs, a position of each alloy layer being defined by the sidewall insulating films,
taper adjusting insulating films formed in contact with the alloy layers on side portions of the sidewall insulating films of the respective MOSFETs, a taper angle made between a cross section of the taper adjusting insulating film in the gate length direction and the substrate surface being set smaller than a taper angle made between the sidewall insulating film and the substrate surface,
a first stress-causing insulating film that applies compressive strains to channels of the p-MOSFETs, the stress-causing insulating film being formed to cover the gate portions of the p-MOSFETs, sidewall insulating films and taper adjusting insulating films,
a second stress-causing insulating film that applies tensile strains to channels of the n-MOSFETs, the stress-causing insulating film being formed to cover the gate portions of the n-MOSFETs, sidewall insulating films and taper adjusting insulating films, and
an interlayer insulating film formed on the first and second stress-causing insulating films.

11. The semiconductor device according to claim 10, wherein the p-MOSFETs and n-MOSFETs are arranged side by side in the gate length direction.

12. The semiconductor device according to claim 11, wherein adjacent MOSFETs commonly use one of the source/drain regions.

13. The semiconductor device according to claim 10, wherein the taper adjusting insulating film is formed of the same material as that of the second stress-causing insulating film.

14. The semiconductor device according to claim 10, wherein the taper adjusting insulating film is formed of one of a silicon oxide film and silicon nitride film.

15. The semiconductor device according to claim 10, wherein the semiconductor substrate is formed of Si and the stress-causing insulating film is formed of a silicon nitride film.

16. The semiconductor device according to claim 10, wherein the sidewall insulating film is formed of a double-layered structure having a silicon oxide film and silicon nitride film.

17. The semiconductor device according to claim 10, wherein the materials and film qualities of the stress-causing insulating films for the pMOSFETs and nMOSFETs are different from each other.

18. A MOS semiconductor device manufacturing method comprising:
forming MOSFETs by forming gate portions on a semiconductor substrate and forming source/drain regions formed on a surface portion of the substrate to respectively sandwich channels under the gate portions,
forming sidewall insulating films on side portions of the gate portions in a gate length direction,
forming alloy layers whose positions are defined by the sidewall insulating films on the source/drain regions,
forming a taper adjusting insulating film to cover the gate portions, sidewall insulating films and alloy layers,
etching back the taper adjusting insulating film to leave portions of the taper adjusting insulating film that lie on lower portions of side portions of the sidewall insulating films and set a taper angle made between the taper adjusting insulating film in a cross section in the gate length direction and the substrate surface smaller than a taper angle made between the sidewall insulating film and the substrate surface,
forming a stress-causing insulating film that applies strains to channels of the MOSFETs to cover the gate portions, sidewall insulating films and taper adjusting insulating film, and
forming an interlayer insulating film on the stress-causing insulating film.
